(19) United States
(12) Patent Application Publication
(10) Pub. No.: US 2006/0018098 A1
(43) Pub. Date: Jan. 26, 2006

(54) PCB board incorporating thermo-encapsulant for providing controlled heat dissipation and electromagnetic functions and associated method of manufacturing a PCB board

(76) Inventors: Adrian Hill, Royal Oak, MI (US); Brian Rogove, Detroit, MI (US)

Correspondence Address: GIFFORD, KRASS, GROH, SPRINKLE & CITKOWSKI, P.C, PO BOX 7021, TROY, MI, 48007-7021, US

(21) Appl. No.: 10/896,523

(22) Filed: Jul. 22, 2004

(51) Int. Cl. H05K 7/20

(52) U.S. Cl. 361/708

(57) ABSTRACT

A circuit board assembly includes a substantially planar shaped printed circuit board (PCB) having a first side and a second side separated by a determined thickness. At least one electrically operable component, typically an LED element, is secured to a selected one of first and second sides of the PCB board, the component generating at least one of a thermal flow pattern and an electromagnetic field. A three-dimensional encapsulant is in-molded around the printed circuit board in such a fashion as to substantially embed the electrically operable component. The encapsulant provides selective heat conductive management of the thermal flow pattern and electromagnetic management of the electromagnetic fields generated by the component.

### BACKGROUND OF THE INVENTION

1. Field of the Invention

The present invention relates generally to circuit board assemblies, and those in particular which incorporate heat and electromagnetic generating components. The present invention in particular teaches a thermo-encapsulant in use with a circuit board which functions to control both thermal and/or electromagnetic properties associated with the PCB board display.

2. Description of the Prior Art

The prior art is well documented with various examples of PCB (circuit) board displays. Such displays utilize heat and electromagnetic generating components, such as LED elements, power transistors, radio frequency (RF) antennas and the like.

A typical PCB board manufacturing process includes the steps of loading a panel into a board handler, screen printing a suitable solder paste onto pads associated with the board handler, placing passive and non odd-form components onto either or both sides of the board and reflowing the solder (such as by reheating) to improve solder joints. Additional steps include attaching LEDs to the PCB and/or solder fixture, and attaching wire to connector systems on the PCB.

Problems associated with existing PCB board displays include issues with excessive heat generation, electromagnetic conductance/interference generated by and among the components populating the circuit board, and environmental insulation of the components associated with the PCB board systems, and in particular to external contaminants (i.e., moisture, dirt and the like), and extreme heat or cold associated with surrounding environmental conditions. Attempts have been made, with varying degrees of success, to individually address these issues.

U.S. Pat. No. 6,428,189, issued to Hochstein, teaches a heat dissipater (substrate) of metal/metallic material disposed in parallel relationship to a circuit board. A circuit board includes a plurality of holes, each surrounding an associated LED element. A heat sink is integrally formed with each LED element and is in thermal contact with the heat dissipater for conveying heat from the LEDs. A thermal coupling agent is disposed between the heat sink and the heat dissipater for providing a full thermal path between the heat sink and the heat dissipater.

Also, a first surface of the circuit board, with the electrical leads soldered or adhesively attached to the traces, faces the heat dissipater. The circuit board is spaced from the heat dissipater and, in FIG. 3, the traces face the heat dissipater. A step in the fabrication of the present invention is the disposing of a thermally insulating cap around the heat sink while disposing the LED on the circuit board to protect the LED from damage during soldering.

U.S. Pat. No. 5,785,418, also issued to Hochstein, teaches an electrically driven LED lamp assembly including an electrically insulating circuit board with LED elements, with positive and negative leads mounted on a first surface. A plurality of pads of thermally conductive plating are disposed on the second side with each pad associated with the leads to conduct heat from each of the leads to one of the pads.

A heat sink includes a base overlaying the second surface and layers of thermally conductive and electrically non-conductive material disposed between the conductive plating and the heat sink to secure the conductive plating and the circuit board to the heat sink while preventing a short between the conductive plating and the heat sink. The assembly is further characterized by a thermally insulating material disposed over the heat sink for sandwiching the heat sink against the conductive plating to limit heat transfer into the heat sink from the outside.

U.S. Pat. No. 5,119,174, issued to Chen, teaches a light emitting diode display with PCB base by which LED members are affixed by a conductive epoxy and bonding wire, and wherein the PCB is punched with a reflector dish on each LED die attach zone so as to reflect and concentrate the light emitted from the LED to increase the luminous intensity of the display. The heat dissipating structure provided by the conductive epoxy is further described as increasing the stability of the forward voltage and wavelength (color) of the LED as well as decreasing the light output degradation in order to prolong the life of the display.

A further subset of prior art references directed to heat dissipating structures includes Shie, U.S. Pat. No. 6,480,389, teaching a heat dissipating structure for LED units including a heat dissipating fluid coolant filled in a hermetically sealed housing where at least one LED chip is mounted on a metallic substrate. Hsing Chen, U.S. Pat. No. 6,713,956, teaches a plurality of light emitting display elements mounted upon a circuit board in turn arranged on a metal plate for providing heat dissipation.

Wu, U.S. Pat. No. 6,652,123, discloses the use of heat sinking circuit rails with LED mounted units, for providing both heat dissipation characteristics, as well as a common electrode for another line of LED elements. Ohlenburger, U.S. Pat. No. 5,012,387, teaches the application of copper and aluminum layers to assist in heat dissipation of circuit board mounted components.

A further subset number of references are directed to LED lamp assemblies incorporating heat sinking or dispersion capabilities and such include Hochstein, U.S. Pat. No. 6,045,240, teaching a heat sink base overlaying an adhesive layer of thermally conductive material for securing the assembly. Electrically non-conductive spacers prevent contact between the conductive plating and the heat sink while maximizing heat transfer. The spacers may comprise a pre-cured coating of the same material as the adhesive or discrete elements. Hochstein, U.S. Pat. No. 5,857,767, further teaches a thermal management system for LED arrays and which in particular includes LEDs being adhesively secured to the ends of adjacent circuit traces with an electrically conductive adhesive comprising an organic polymeric material compounded with a metal.

A yet further subset of references teaches various EMI and EMR insulating schemes and reference is made by example to Hughes, U.S. Pat. No. 5,566,052, which teaches an electronic device with an EMI shield surrounding an electronic component on a substrate. A heat sink extends through an opening in the shield from heat conductive contact with the component to a position outside the shield. The heat sink is also disclosed as operating in an EMI shield capacity and which is stressed to hold the heat sink positively in heat conducting contact with the components. Other examples of EMI and EMR insulating schemes include those set forth in Weber, U.S. Pat. No. 5,335,147; Perkins, U.S. Pat. No. 6,490,173; and Fajardo, U.S. Pat. No. 6,490,173.

### SUMMARY OF THE PRESENT INVENTION

The present invention is a printed circuit board assembly upon which is applied a three-dimensional and in-molded encapsulant, the purpose for which being to provide either or both of controlled thermal management (conduction) and electromagnetic compatibility of electrically operable components (e.g., LED elements, power transistors, radio frequency antennas) secured to either or both of first and second facing sides of the circuit board. In particular, the present invention accomplishes heat management and electromagnetic shielding governing through the application of a three-dimensional and in-molded encapsulant which surrounds the PCB board, as well as substantially or entirely embedding the electrically operable components, depending upon the application of such as an LED element, and as opposed to a power transistor.

In a preferred embodiment, the in-molded encapsulant is provided as a thermoplastic material having a chemical composition exhibiting an elevated melting point. The encapsulant is applied over the circuit board assembly, such as after substantial assembly of a PCB board, in order to provide heat dissipation or thermal management of localized hot spots resulting from the use of such as LED (light emitting diode) elements in the PCB assembly.

At least one mounting bracket may be in-molded into the three-dimensional encapsulant in order to facilitate mounting the PCB assembly to an operating location. The encapsulant accordingly functions as an environmental sealing package and one which protects the in-molded PCB board and associated components from the effects of moisture, contaminants and the like.

An objective of the use of the encapsulant in a thermal management application is to evenly distribute, across substantially all of the exterior surfaces of the applied encapsulant, the heat generated (in localized fashion) by the electrical components. A further application of the thermoplastic encapsulant, operating either in combination or independently of the thermal management capabilities, is to provide electromagnetic shielding or insulation resulting from EMI/EMR, generated by certain of the electrically operable components mounted to the PCB board, and as it relates to both other components mounted to the circuitry as well as to electrically operable systems both proximately located and independent from the PCB board assembly.

In accomplishing electromagnetic shielding, the encapsulant layer may, in one application, incorporate a combination of an outer shielding layer and an inner insulative layer. Additionally, a ferrous based EMC countermeasure may be incorporated into the in-molded encapsulant in order to either protect or shield localized emitting components.

In accomplishing thermal management, the encapsulant layer(s) may also be both thermally shielding and inner-conductive. Additionally, a ferrous or other high conductive countermeasure can be both electromagnetic and thermally effective in its design.

### BRIEF DESCRIPTION OF THE DRAWINGS

Reference will now be made to the attached drawings, when read in combination with the following detailed description, wherein like reference numerals refer to like parts throughout the several views, and in which:

FIGS. 1A and 1B are perspective and side views of a basic PCB board, exhibiting thermal conducting pin holes and associated through apertures according to a first assembly step of the present invention;

FIGS. 2A and 2B are perspective and side views of a succeeding assembly step and illustrating LED elements fixed to the pin holes formed within the PCB;

FIGS. 3A and 3B illustrate perspective and side views of various electrical components secured to the PCB;

FIGS. 4A and 4B are perspective and side views of metallic or other suitable heat conductive elements secured to the PCB, such as to opposite sides of a through aperture, in order to flow heat from and to components associated with the assembly;

FIGS. 5A and 5B are perspective and side views illustrating the incorporation of electromagnetic compatibility devices into the PCB assembly;

FIGS. 6A and 6B are perspective and side views of a yet succeeding assembly step illustrating a three-dimensional thermo-encapsulant applied over the assembled board of FIGS. 5A and 5B;

FIG. 7 is a two-dimensional cutaway illustration of a further variant of PCB board assembly which illustrates a three-dimensional encapsulant operating in an exclusively thermal management application;

FIG. 8 is a two-dimensional cutaway illustration of a further variant of PCB board assembly illustrating a suitable three-dimensional encapsulant operating in an electromagnetic countermeasuring (management) application;

FIG. 9A is an illustration of a substantially completed PCB board display prior to application of a suitable 3D thermoplastic encapsulant;

FIG. 9B illustrates the PCB board assembly of FIG. 9A, with the application of a three-dimensional encapsulant and associated in-molded support bracketry to provide environmental an environmental proof packaging;

FIG. 10A is side cutaway illustration of a PCB board assembly and in particular of a plurality of heat dissipation arrows associated with the PCB board for illustrating the pathways of heat dissipation, and in particular the creation of hot spots, associated with the un-encapsulated PCB board assembly;

FIG. 10B is a succeeding side cutaway of the PCB board assembly of FIG. 10A illustrating the manner by which the heat dissipation arrows are affected by the application of the three-dimensional conductive encapsulant;

FIG. 11A is a cutaway illustration of a PCB board display, incorporating a plurality of electromagnetic generating components, and illustrating uncontrolled electromagnetic radiation associated with an un-encapsulated PCB assembly;

FIG. 11B is a succeeding side cutaway of the PCB board assembly of FIG. 11A illustrating the manner by which the EMC fields are insulated or otherwise managed through the application of a three-dimensional encapsulant, and further including the incorporation of at least one ferrous based EMC countermeasure molded adjacent to a key emitting component, according to the present invention;

FIG. 12A is an illustration of a pre-encapsulated PCB board assembly and incorporating heat-generating power transistors in substitution of LED elements according to a further preferred embodiment of the present invention;

FIG. 12B is a succeeding illustration of a three-dimensional encapsulant applied over assembly of FIG. 12A and further including the application of at least one thermal conduit/heat spreading component in-molded into the encapsulant;

FIG. 13A is an illustration of a pre-encapsulated PCB board assembly incorporating a loop-type radio frequency generating antenna and associated high power RF generating circuitry;

FIG. 13B is an illustration of a succeeding and heat dissipating thermal encapsulant applied to the PCB board assembly of FIG. 13A; and

FIG. 13C is an illustration of a three-dimensional thermal encapsulant, alternate to that shown in FIG. 13B, showing an optional thermal/EMC shield including a metalized encapsulant layer in order to provide directional RF shielding with thermal management according to the present invention.

### DETAILED DESCRIPTION OF THE PREFERRED EMBODIMENTS

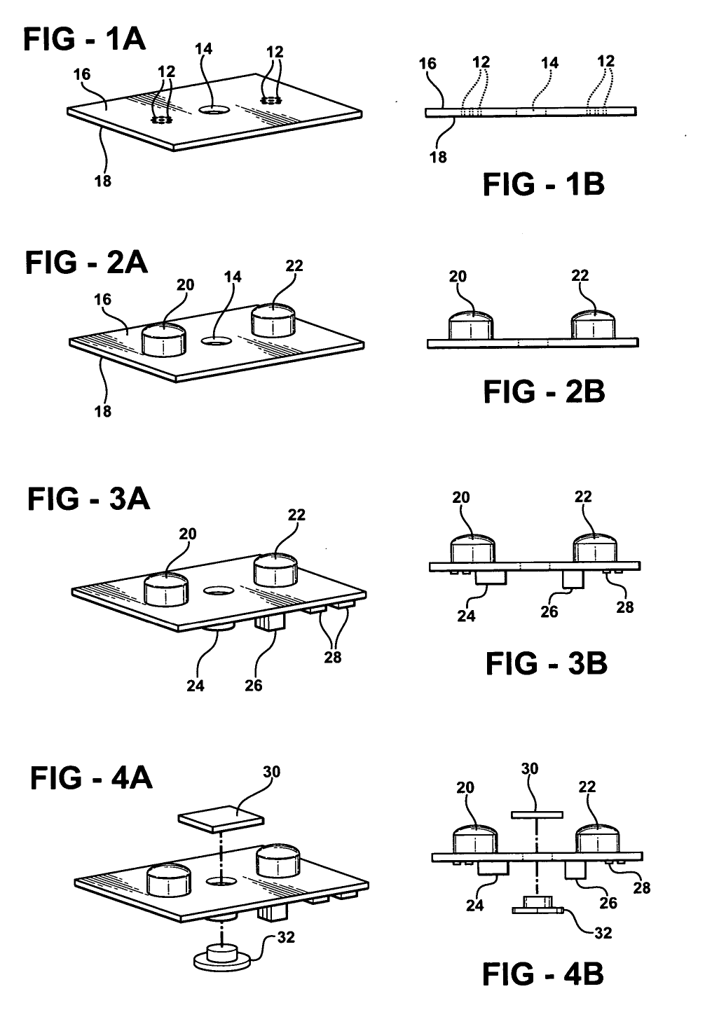

Referring now to FIGS. 1-6, an assembly scheme is illustrated for manufacturing a PCB board and assembly which includes the application of a three-dimensional and in-molded encapsulant for providing either or both of thermal management and electromagnetic shielding of electrically operable components associated with the PCB assembly. In particular, and as will be described in additional detail, the present invention provides an environmentally sealed package for the PCB assembly which accomplishes either or both of heat management and electromagnetic shielding through the application of a three-dimensional and in-molded thermoplastic encapsulant, the same surrounding the PCB board as well as substantially or entirely embedding the electrically operable components.

Referring first to FIGS. 1A and 1B, both perspective and side views are illustrated at 10 of a basic printed circuit (PCB) board, see as generally shown at 10 in FIG. 1A, such as which exhibits thermal conducting pin holes 12 (such as for seating and engaging a suitable heat generating component as will be subsequently described) and typically at least one associated through aperture 14. As will be also further described in reference to the corresponding method of manufacturing a PCB board assembly, initial production of the PCB board is accomplished utilizing conventional steps of loading a panel into a handler and screen printing a solder paste (such as in particular a 63/37 ratio of SnPb) onto associated pads which are then transferred to either of both first 16 and second 18 sides of the PCB board 10.

Referring further to FIGS. 2A and 2B, perspective and side views are shown of a succeeding assembly step of the PCB board, which in particular illustrates light emitting diode (hereinafter referenced as LED) elements 20 and 22 fixed to the sets of thermal pin holes 12 formed within the PCB board. As will be described, the present invention is particularly suited for use LED elements, the same exhibiting a high degree of thermal emission and which, absent any other application, tends to create localized and potentially damaging hot spots upon the PCB board. As also illustrated, the LED elements 20 and 22 are secured to selected side 16 of the board in adjacent fashion to the through aperture 14, it being further understood that such electrically operable components are capable of being secured to either or both the first 16 and second 18 sides of the PCB board.

Referencing now FIGS. 3A and 3B, perspective and side views are shown of various electrical components, e.g. at 24, 26, 28, secured to the second (under) side 18 of the PCB. The components are typically selected from items providing features such as driver regulation, protection, thermal sensing, and the like.

As shown in further reference to the perspective and side views of FIGS. 4A and 4B, a metallic or other suitable heat conductive (heat spreading) element is secured to the PCB board. As illustrated, this may consist of a two-piece assembly 30 and 32 such as which interengages to opposite sides of the PCB board and via the through apertures, in order to flow heat from and to components associated with the assembly.

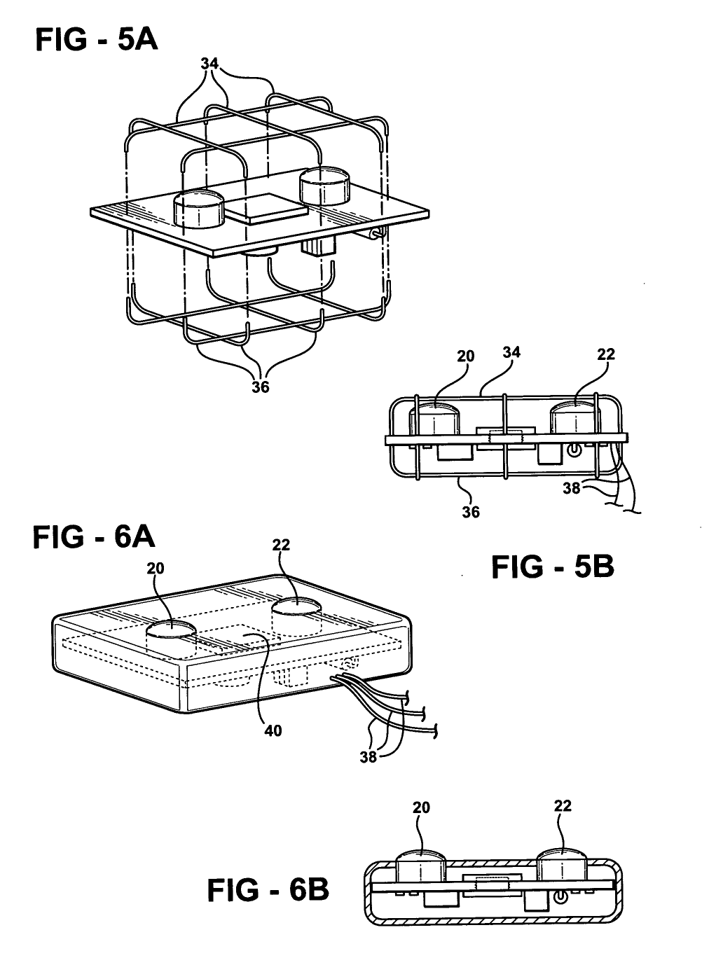

FIGS. 5A and 5B are perspective and side views illustrating the incorporation of electromagnetic compatibility devices, these being representatively illustrated at 34, 36, et seq., into the PCB assembly. Such are generally understood to include, without limitation, RF shielding and Faraday cage devices. As also shown at 38, any plurality of wires may be secured to given locations of the PCB board in order to transfer power (and data/signal information where applicable) both to and from the assembly.

Referring now to FIGS. 6A and 6B, perspective and side views of a yet succeeding assembly step are illustrated which show a three-dimensional thermo-encapsulant 40 applied over the assembled board of FIGS. 5A and 5B as well as to the connecting portions of the wires 38. The encapsulant 40 is provided in a generally three-dimensional shape “that conforms to the shape/size of the PCB board” (such as the rectangular configuration illustrated which encases the PCB board, the associated passive components, and which further substantially embeds the LED elements 20 and 22 while permitting the top portions to project beyond a surface of the encapsulant). As will be described in additional detail with reference to the succeeding several embodiments, the encapsulant 40 provides a robust and environmentally sealing package, as well as thermal and/or electromagnet management of the heat and/or EMI emitting components associated with the PCB board.

In a preferred embodiment, the encapsulant is in-molded over the assembled PCB board of FIGS. 5A and 5B, and further consists of a thermoplastic material exhibiting a sufficiently high melting point such that it will not soften or deform in use with such as the heat generating LED elements. The material content (or multi-layering as will be subsequently described) of the encapsulant is such that it can exhibit any combination of heat conductive or insulative properties, and such that it can be tailored to the heat emitting profile associated with the PCB board assembly in order to provide a desired degree of dissipation (or redirection) of the thermal profile.

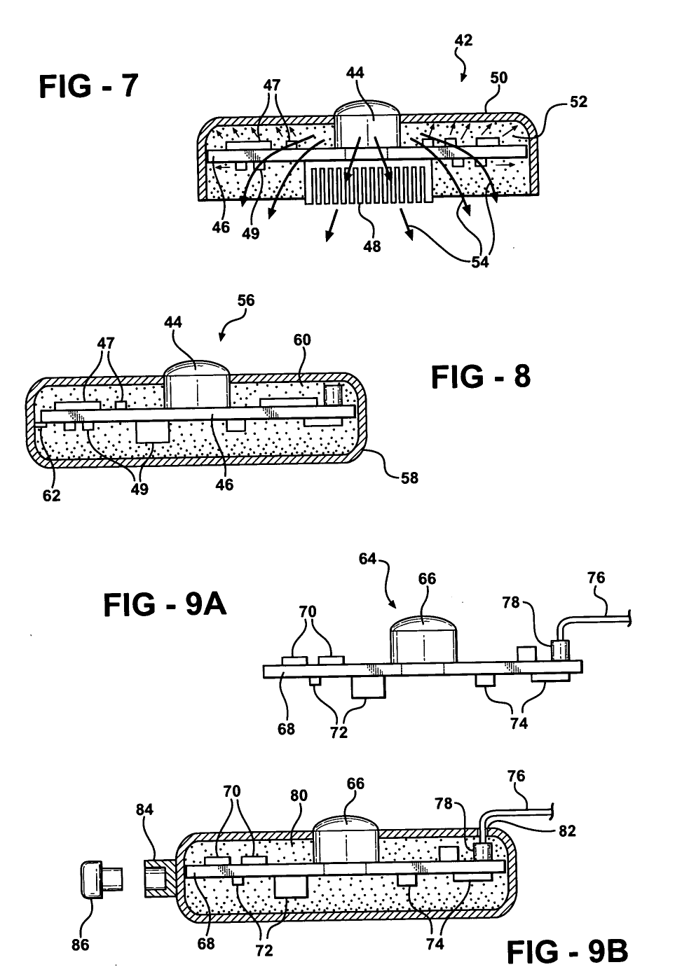

Referring now to FIG. 7, a two-dimensional cutaway illustration is generally shown at 42 of a further variant of PCB board assembly which illustrates a three-dimensional encapsulant operating in an exclusively thermal management application. In particular, an LED element 44 is shown secured to a PCB board 46, such as opposite an optional heat sink/heat conduit element 48. Various other electrical components 47 and 49 are shown in association with the upper and lower layers.

The three-dimensional encapsulant includes an outer insulative layer 50 (as shown extending along a top and sides of the three-dimensional packaging) and an inner conductive encapsulant filler 52. In this fashion, a top (or front) side of the PCB assembly package emits a relatively cooler temperature than that associated with a rear side, and through which the conductive encapsulant filler 52 facilitates the dissipation of heat as referenced by arrows 54.

Referring to FIG. 8, a two-dimensional cutaway illustration is shown at 56 of an optional variant of a PCB board assembly, this again including the illustration of the LED element 44 and associated PCB board 46. The three-dimensional encapsulant in this variant is suited for providing electromagnetic shielding and includes both an outer metallic (such as highly magnetic) layer, in combination with an electrically insulative filler 60. It is also envisioned that an optional conductive bridge 62 may be provided to electrically connect (or ground) the PCB board to the outer layer 58.

As shown in reference to FIG. 9A, a substantially completed PCB board assembly 64 is illustrated prior to application of a suitable three-dimensional thermoplastic encapsulant. The assembly 64 includes a heat producing LED element 66 secured to a PCB board 68; various electronic components 70, 72, 74, et seq.; and a wiring harness 76 extending to a location associated with the PCB board and secured in place by a spiraling wiring connector 78 or wire harness.

Referring now to FIG. 9B, further illustrated is the application of a three-dimensional encapsulant 80 which provides the function of sealing the board and components (including substantially the LED elements) from the effects of the surrounding environment. An extra mechanical support can be molded at 82, such as to reinforce the wire harness connection 76, and it is also envisioned that an integrally molded fixing element formed at 84 (such as a fixing hole, screw/bolt hole or optional metal tube insert i.e. single or multiple fixings) can operate as an associated and in-molded support bracket. A brass insert 86 or the like can also be utilized to facilitate securing the fixing element 84 and, in total, to provide an environmental proof packaging.

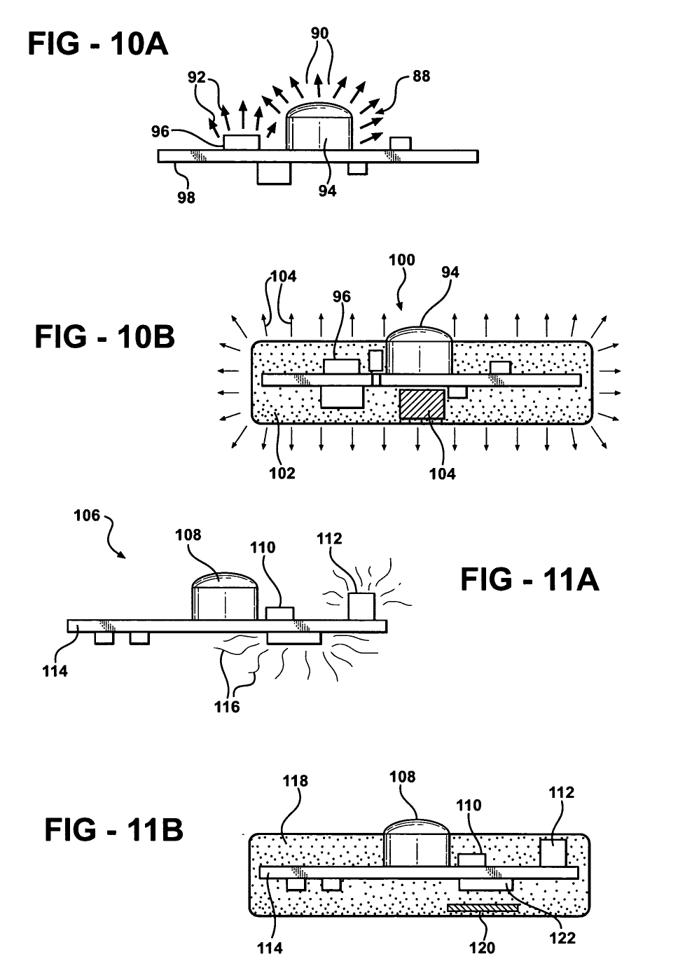

Referring now to FIG. 10A, a side cutaway illustration of a PCB board assembly is shown at 88 of a plurality of heat dissipation arrows 90 and 92, associated with LED element 94 and electronic drive component 96 secured to a PCB board 98. The congregation and direction of the arrow pathways 90 and 92 of heat dissipation illustrates in particular the creation of hot spots, these again typically being associated with an unencapsulated PCB board assembly.

As illustrated with succeeding reference to the illustration of FIG. 10B, a cutaway 100 of the PCB board assembly of FIG. 10A illustrates the manner by which the heat dissipation arrows are affected by the application of a three-dimensional (typically highly thermally conductive) encapsulant 102. In particular, the application of the encapsulant results in the heat profile (previously congregated in localized fashion as shown again by directional arrows 90 and 92 in FIG. 10A) to be redirected in a substantially even and spaced manner, see at 104, across the top, side and bottom faces of the encapsulant packaging.

Referencing now FIG. 11A, a cutaway illustration is shown at 106 of a PCB board display, incorporating a plurality of electromagnetic generating components 108, 110 and 112 secured to a PCB board 114 (such as again referenced by drive circuitry container fast switching elements, e.g., an LED driven by switch mode power supply) and illustrating uncontrolled electromagnetic radiation fields 116 associated with an unencapsulated PCB assembly. FIG. 11B references in succeeding fashion the PCB board assembly of FIG. 11A by which the EMC fields are insulated or otherwise managed through the application of a three-dimensional encapsulant 118. Of additional note is the incorporation of at least one ferrous based EMC countermeasure, see plate 120, molded adjacent to a key emitting component, e.g. at 122, and which, in combination with the properties associated with the three-dimensional encapsulant, provides an extra measure of shielding action to the assembly.

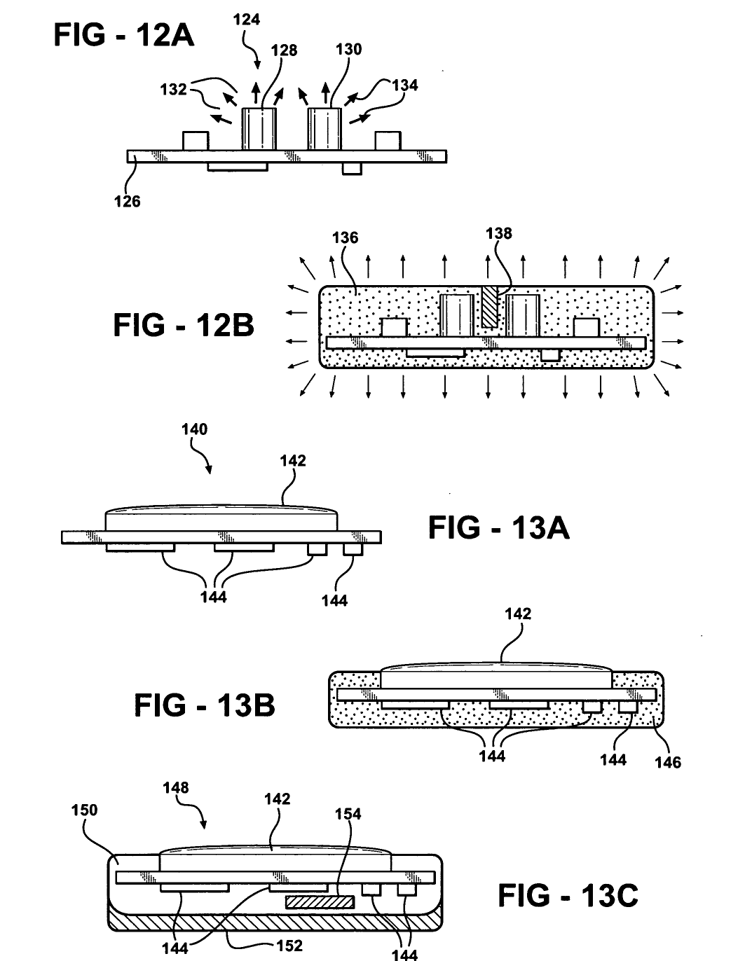

FIG. 12A is an illustration 124 of a pre-encapsulated PCB board assembly 126 incorporating heat generating power transistors 128 and 130, in substitution of the LED elements referenced in the earlier disclosed preferred embodiments. The localized heat profiles (see directional arrows 132 and 134 identifying “hot spots”) associated with the power transistors 128 and 130 are again more evenly distributed through the application of a three-dimensional encapsulant 136, see FIG. 12A. As with earlier embodiments, at least one thermal conduit/heat spreading component 138 may be applied in an in-molded fashion into the encapsulant 136.

Referring further to FIG. 13A, an illustration 140 is shown of a pre-encapsulated PCB board assembly, in this variant incorporating a loop-type radio frequency generating antenna 142 and associated high power RF generating (driver) circuitry 144, these being secured to opposite facing surfaces of the PCB board. FIG. 13B is an illustration of a succeeding heat dissipating thermal encapsulant 146 applied to the PCB board assembly of FIG. 13A such that the RF antenna 142 is molded in exposed fashion along a surface of the encapsulant 146, and such as further to provide mechanical support for the antenna. As is also known, the encapsulant 146 may also provide heat dissipation of the heat generating components 144 secured to the underside surface of the PCB board.

Referring finally to FIG. 13C, an illustration is shown at 148 of an optional variant of a three-dimensional thermal encapsulant 150, alternate to that shown in FIG. 13B, and showing an optional thermal/EMC shield including a metalized encapsulant layer 152 (see along underside profile of encapsulant) in order to provide directional RF shielding with thermal management of the drive circuitry components 144 located on the underside surface of the PCB board assembly. As illustrated in previous embodiments, a directional RF shielding component 154 may also be in-molded into the encapsulant 150 in order to provide additional EMI/EMR management.

A manufacturing process for assembling a printed circuit board assembly is also disclosed and includes the steps of screen printing a solder paste onto at least one side of a circuit board panel, securing at least one passive component upon the panel in communication with the solder paste, and attaching at least one electrically operable and heat/EMI generating component to the panel. Additional steps include attaching a plurality of wires to at least one location associated with the circuit board and at least one of the components as well as molding a three-dimensional encapsulant about the circuit board and a connecting portion associated with the wires, the encapsulant substantially (or entirely) surrounding the electrically operable components and providing at least one of controlled heat conduction and electromagnetic shielding to the assembly.

Additional steps include in-molding at least one bracket within the three-dimensional encapsulant, such that the encapsulant may function as a durable and environmentally sealing package. The step of attaching at least one electrically operable and heat/EMI generating component to the panel may further include the step of attaching at least one of an LED element, a power transistor and a radio frequency antenna and circuit driver.

Yet additional steps include forming at least one thermal pin hole through the panel, as well as forming at least one aperture through said panel. At least one heat conductive element including first and second heat spreader pieces is secured against first and second sides and interconnected through the through aperture.

Other steps include molding the encapsulant with an outer insulated encapsulant layer over an inner conductive encapsulant filler, such that at least a portion of the inner conductive encapsulant is exposed to an exterior of the circuit board assembly. The step of molding the three-dimensional encapsulant may further include applying an outer electromagnetic shielding over an electrically insulative encapsulant filler. Yet additional steps include incorporating at least one heat conductive element within the molded three-dimensional encapsulant, in a determined spaced relationship relative to the circuit board panel and components, incorporating at least ferrous-based electromagnetic countermeasure within the molded three-dimensional encapsulant at a location proximate to at least one selected EMI generating component, as well as molding the encapsulant in dual layers incorporating an electrically grounding connecting to the circuit board panel.

Having described our invention, other and additional preferred embodiments will become apparent to those skilled in the art to which it pertains, without deviating from the scope of the appended claims:

We claim:

1. A circuit board assembly, comprising:
a substantially planar shaped printed circuit board having a first side and a second side separated by a determined thickness;
at least one electrically operable component secured to a selected one of said first and second sides, said component generating at least one of a thermal flow pattern and an electromagnetic field; and
a three-dimensional encapsulant molded around said printed circuit board and substantially embedding said electrically operable component, said encapsulant providing selective heat conductive management of said thermal flow pattern and electromagnetic management of said electromagnetic fields generated by said component.

2. The circuit board assembly as described in claim 1, said encapsulant further comprising a thermoplastic material exhibiting an elevated melting point.

3. The circuit board assembly as described in claim 1, further comprising a plurality of wires connected to at least one location associated with said circuit board and about which is molded said encapsulant.

4. The circuit board assembly as described in claim 1, further comprising in-molded bracketry extending from locations associated with said three-dimensional encapsulant, said encapsulant functioning as an environmental casing for said PCB assembly.

5. The circuit board assembly as described in claim 1, said at least one electrically operable component further comprising at least one of an LED element, a power transistor, and a radio frequency antenna and circuit driver.

6. The circuit board assembly as described in claim 1, said printed circuit board exhibiting a specified shape and size and including at least one of thermal conducting pin holes and associated through apertures.

7. The circuit board assembly as described in claim 6, further comprising at least one heat conductive element including first and second heat spreader pieces secured against said first and second sides and interconnected through said through aperture.

8. The circuit board assembly as described in claim 1, further providing at least one electromagnetic countermeasure incorporated into said circuit board and selected from the group including a RF shield and a Faraday cage.

9. The circuit board assembly as described in claim 1, said three-dimensional encapsulant further comprising an outer insulated encapsulant layer, an inner conductive encapsulant filler bordering against said outer layer, at least a portion of said inner conductive encapsulant being exposed to an exterior of said circuit board assembly.

10. The circuit board assembly as described in claim 1, said three-dimensional encapsulant further comprising an outer electromagnetic shielding layer and an electrically insulative encapsulant filler.

11. The circuit board assembly as described in claim 1, said three-dimensional encapsulant exhibiting a specified shape and size and further comprising an environmental sealant about said printed circuit board and electrically operable components.

12. The circuit board assembly as described in claim 1, further comprising at least one heat conductive element in-molded within said encapsulant in a determined spaced relationship relative to said circuit board and electrically operable components.

13. The circuit board assembly as described in claim 1, further comprising a ferrous based electromagnetic countermeasure in-molded within said encapsulant at a location proximate to selected electromagnetic generating components.

14. The circuit board assembly as described in claim 13, said three-dimensional encapsulating further comprising dual encapsulating layers with a ground connection.

15. A manufacturing process for assembling a printed circuit board assembly, comprising the steps of:
screen printing a solder paste onto at least one side of a circuit board panel;
securing at least one passive component upon said panel in communication with said solder paste;
attaching at least one electrically operable and heat/EMI generating component to said panel;
attaching a plurality of wires to at least one location associated with said circuit board and at least one of said components; and
molding a three-dimensional encapsulant about said circuit board and a connecting portion associated with said wires, said encapsulant substantially surrounding said electrically operable components and providing at least one of controlled heat conduction and electromagnetic shielding to said assembly.

16. The manufacturing process as described in claim 15, further comprising the step of in-molding at least one bracket within said three-dimensional encapsulant.

17. The manufacturing process as described in claim 15, said step of attaching at least one electrically operable and heat/EMI generating component to said panel further comprising the step of attaching at least one of an LED element, a power transistor and a radio frequency antenna and circuit driver.

18. The manufacturing process as described in claim 15, further comprising the step of forming at least one thermal pin hole through said panel.

19. The manufacturing process as described in claim 15, further comprising the step of forming at least one aperture through said panel.

20. The manufacturing process as described in claim 19, further comprising the step of attaching at least one heat conductive element including first and second heat spreader pieces secured against first and second sides and interconnected through said through aperture.

21. The manufacturing process as described in claim 15, said step of molding a three-dimensional encapsulant further comprising applying an outer insulated encapsulant layer over an inner conductive encapsulant filler, at least a portion of said inner conductive encapsulant being exposed to an exterior of said circuit board assembly.

22. The manufacturing process as described in claim 15, said step of molding a three-dimensional encapsulant further comprising applying an outer electromagnetic shielding over an electrically insulative encapsulant filler.

23. The manufacturing process as described in claim 15, further comprising the step of incorporating at least one heat conductive element within said molded three-dimensional encapsulant in a determined spaced relationship relative to said circuit board panel and said components.

24. The manufacturing process as described in claim 15, further comprising the step of incorporating at least ferrous based electromagnetic countermeasure within said molded three-dimensional encapsulant at a location proximate to at least one selected EMI generating component.

25. The manufacturing process as described in claim 15, further comprising the step of molding said three-dimensional encapsulant in dual layers incorporating an electrically grounding connecting to said circuit board panel.
